(19) United States
(12) Patent Application Publication
(10) Pub. No.: US 2005/0201134 A1
(43) Pub. Date: Sep. 15, 2005

(54) Memory component with asymmetrical contact row

(75) Inventor: Henning Hartmann, Tegernheim (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/070,281

(22) Filed: Mar. 3, 2005

(30) Foreign Application Priority Data
Mar. 15, 2004 (DE) 10 2004 012 553.8

(51) Int. Cl. G11C 5/06

(52) U.S. Cl. 365/63

(57) ABSTRACT

The invention relates to a memory component (11), with numerous contact connections (12a, 12b, 12c), and with at least two memory cell arrays (13a, 13b), each containing numerous memory cells, whereby the contact connections (12a, 12b, 12c) are arranged to lie in an area (17) between a central axis (a)—running between the arrays (13a, 13b)—, in particular the spine of the memory component (11), and one of the arrays (13a).

### CLAIM FOR PRIORITY

This application claims priority to German Application No. 10 2004 012 553.8 filed Mar. 15, 2004, which is incorporated herein, in its entirety, by reference.

The invention relates to a memory component according to the preamble of claim 1.

With memory components, in particular semi-conductor memory components, a distinction is made between so-called function memory components (e.g. PLAs, PALs, etc.), and so-called table memory components, e.g. ROM components (ROM=Read Only Memory and/or fixed memory), and RAM-components (RAM=Random Access Memory and/or Read/Write memory), for instance DRAMs (DRAM=Dynamic Random Access Memory), SRAMs (SRAM=Static Random Access Memory), etc.

The corresponding components are installed in housings provided with appropriate contact pins.

The housing contact pins are connected—e.g. via bonding wires—with corresponding contact connections provided on each semi-conductor component (so-called “pads”).

A RAM component is a memory device in which data can be stored after an address has been specified, and later read out again under this address.

The corresponding address can for instance be input into the RAM component by means of so-called address pins of the component housings, and the address pads of the component connected thereto.

For in- and outputting data several, e.g. 16, 32, etc. so-called data input/output pins—connnected to corresponding data pads or I/O pads on the semi-conductor component—can be provided.

By applying an appropriate control signal (for instance a read/write signal) to a corresponding control pin, in particular a read/write selector pin connected to a read/write selector pad, it can be decided whether data should be (instantly) stored or read out.

Because a RAM component needs to be provided with as many storage cells as possible, it becomes important for the creation of these cells to be kept as simple as possible. With so-called SRAMs (SRAM=Static Random Access Memory) the individual memory cells for instance consist of a few, e.g. six, transistors, and with so-called DRAMs (DRAM=Dynamic Random Access Memory) usually of only one single suitably controlled capacitor, with the capacitance of which one bit at a time can be stored in the form of charge. This charge only persists for a short period, which means that a so-called “refresh” must be performed regularly, e.g. ca. every 64 ms.

For technical reasons the individual memory cells of RAM components are arranged in a rectangular matrix and/or array.

In order to achieve a correspondingly high total storage capacity, several, for instance four essentially rectangular arrays, essentially evenly distributed over the surface area of the chip, can be provided in a single RAM component.

The above address must then be increased to the number of bits required for addressing and/or selecting the array in question.

The above component contacts or pads (address pads, I/O pads, control pads, etc.) are arranged to lie next to each other in a central chip area (the so-called “spine”), exactly halfway between the upper and the lower two arrays, i.e. in a row of contacts lying in the spine area.

In the above spine area provision can also be made for central control logic devices—containing appropriate multiplexers and/or de-multiplexers, timers, registers, etc for securing the functioning of the memory component—jointly allocated to all arrays (as well as further elements, e.g. central data lines (central data bus), and/or further—central or decentral—logic elements used by all arrays, etc., etc.).

The structural dimensions of the lines, logic elements, memory cells, etc. provided on the component—for instance created by the use of appropriate lithographic processes—have steadily diminished over the last years.

This does not apply—or only applies to a limited extent—to the size of the above component contacts or pads (address pads, I/O pads, control pads, etc.); these may not be smaller than a particular minimum size, for instance to secure the reliability of the semi-conductor component tests performed at wafer level (in which the pads are contacted, for instance by corresponding probe card contact pins), and to withstand the mechanical stresses occurring during the subsequent soldering of the above bond wire, etc.

No central circuit structures may be installed below the pads—especially no elements of the above central control logic—in particular due to the high mechanical stresses occurring during manufacture, the strong electromagnetic fields occurring as a result of the relatively high voltages arising from the signals at the pads, etc.

The invention is aimed at making available a novel memory component.

It achieves these and other aims by means of the subject matter of claim 1.

Advantageous further developments of the invention are described in the subsidiary claims.

In terms of a basic concept of the invention, a memory component is made available, which has numerous contact connections and at least two memory cell arrays, each containing numerous memory cells, whereby the contact connections are arranged in an area between a central axis (a)—running between the arrays—, in particular the spine of the memory component, and one of the arrays.

Especially advantageously, the contact connections are arranged in a single row lying adjacent to each other, or in several rows, e.g. adjacent to each other in two or more parallel rows.

Preferably the contact connection row and/or the contact connection rows are offset from the central axis and/or the spine, in particular in the direction of one of the arrays.

For instance, the contact connection row and/or contact connection rows can be offset in parallel in relation to the central axis and/or the spine.

Advantageously the area in which the contact connections are arranged is directly adjacent to one of the arrays.

In a preferrable embodiment of the invention, elements of a central control logic, jointly controlling at least two arrays, are arranged on a further area of the memory component, which lies between the area in which the contact connections are arranged and the other array.

Advantageously the elements for the central control logic can be of relatively large dimensions—which is made possible by the relatively extensive width of the above further area, which the invention allows—and/or jointly designed pre-synthesized elements can be used for several different memory components.

Below the invention is more closely described with the aid of the attached illustrations. In the illustrations

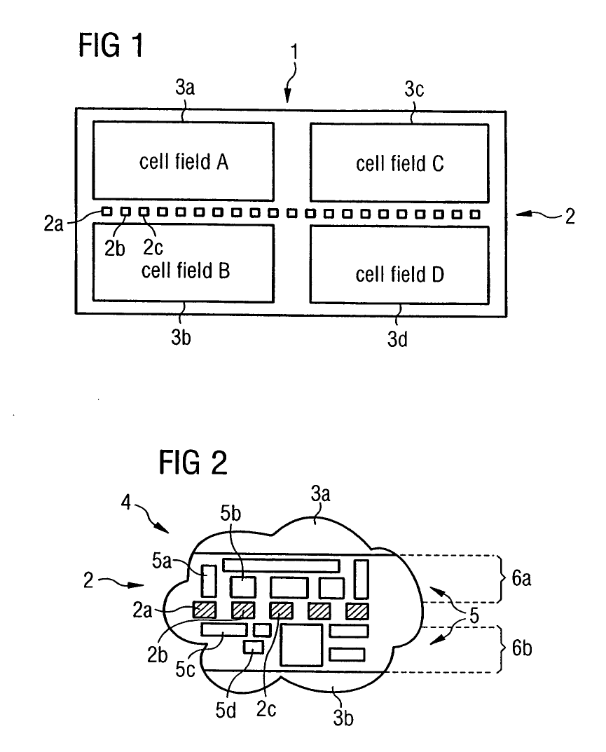

FIG. 1 shows a schematic representation of a state of the art semi-conductor memory component;

FIG. 2 shows a schematic detailed representation of a section of the semi-conductor memory component shown in FIG. 1;

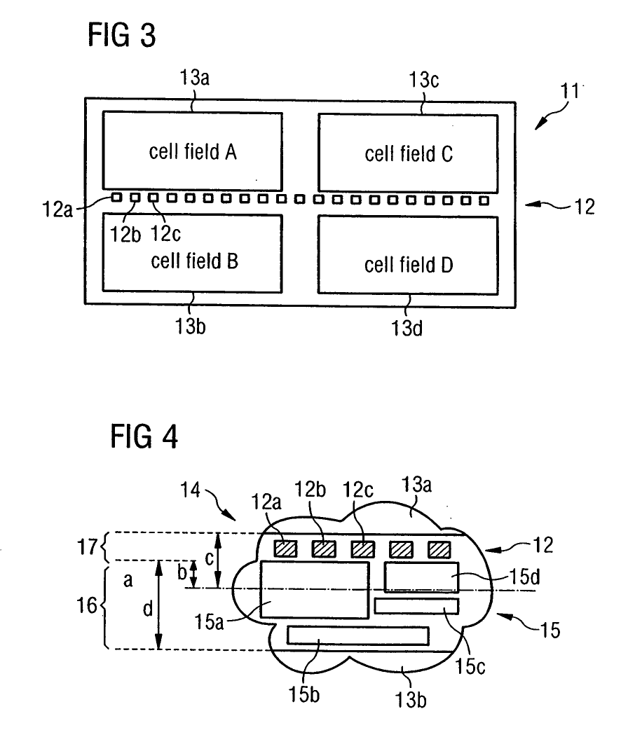

FIG. 3 shows a schematic representation of a semi-conductor memory component according to an embodiment example of the present invention; and

FIG. 4 shows a schematic detailed representation of a section of the semi-conductor memory component shown in FIG. 3.

In FIG. 1 a schematic representation of a state of the art semi-conductor memory component 1 is shown.

The semi-conductor memory component 1 may be a DRAM memory component (DRAM=Dynamic Random Access Memory and/or dynamic read-write memory) e.g. one based on CMOS technology, e.g. a DDR-DRAM (DDR-DRAM=Double Data Rate—DRAM and/or DRAM with double data rate).

The component 1 can be installed in a housing provided with corresponding contact pins.

The housing contact pins are connected—e.g. via bonding wires (not shown here)- to corresponding contact connections 2a, 2b, 2c (so-called “pads” provided on the component 1).

In the semi-conductor memory component 1—after a corresponding address has been applied to the housing address contact pins (not shown here), and thereby to the address input contact connections connected to them and/or to pads of the memory component 1—data can be stored under the address in question and later read out again under this address.

A number m of data contact connections and/or pads—connected to corresponding housing data contact pins—has been provided for inputting and outputting data, e.g. m=16, 32, or 64 data contact pads.

By applying an appropriate signal (e.g. a read/write signal) to a corresponding read/write selection connection contact and/or pad—connected to a corresponding housing read/write-contact pin—it can in each case be decided whether data is to be stored or read out.

The data input into the semi-conductor memory component 1 is stored there in corresponding memory cells and later read out again from the corresponding memory cells.

Each memory cell may consist of a few, in particular only of a single appropriately controlled transistor, with the capacitance of which one bit at a time can be stored as a charge.

A particular number of memory cells is in each case arranged to lie in a rectangular and/or square matrix and/or array 3a, 3b, 3c, 3d, i.e. in a corresponding cell field, so that—corresponding to the number of memory cells present—for instance 32 Mbit, 64 Mbit, 128 Mbit, 256 Mbit etc. can be stored in a matrix and/or array 3a, 3b, 3c, 3d.

As is further shown in FIG. 1, the semi-conductor memory component 1 contains a number k of memory cell arrays 3a, 3b, 3c, 3d (here e.g. four, which are always essentially identically constructed and evenly distributed over the surface of the component), which then creates a corresponding total memory capacity of e.g. 128 Mbit, 256 Mbit, 512 Mbit, and/or 1,024 Mbit (and/or 1 Gbit) for the semi-conductor memory component 1.

The above address, applied to the address input contact connections and/or pads, may contain a corresponding number of bits (e.g. two), which serve to address the required memory cell array 3a, 3b, 3c, 3d during the storage or reading out of data.

As is apparent from FIG. 1, the above contact connections and/or pads 2a, 2b, 2c (i.e. the data pads, the address pads, the read/write selection pad, and possible further pads (not mentioned above), e.g. a chip select pad, etc., etc.) are arranged—lying adjacent to each other—in a central chip area (the so-called “spine”) which lies exactly between the two arrays 3a, 3c (on top in the illustration), and the arrays 3b, 3d (at the bottom in the illustration), i.e. in the form of a contact row 2 (pad row 2) lying in the spine area.

FIG. 2 shows a schematic detail representation of a section 4 of the the semi-conductor memory component 1 shown in FIG. 1.

As is apparent from FIG. 2, provision is also made (in the above central spine area of the semi-conductor memory component 1) for a jointly operating control logic 5 (as well as further elements, for instance central data lines (central data bus) and/or further—central or decentralized logic elements and/or lines etc., etc.) jointly used by all arrays 3a, 3b, 3c, 3d, etc., etc. for securing the functioning of the memory component containing the corresponding elements 5a, 5b, 5c, 5d (e.g. appropriate multiplexers and/or de-multiplexers, timers, registers) jointly allocated to all central arrays 3a, 3b, 3c, 3d and/or jointly controlling them.

In terms of FIG. 2, the above elements 5a, 5b, 5c, 5d (i.e. the elements allocated to the central control logic 5 and the above—further—elements) are in each case arranged—in separated form—into two areas 6a, 6b (in the illustration shown lying above and below pad row 2 (contact row 2)), i.e. into a first area 6a, lying between pad row 2 and the arrays 3a, 3c—lying above in the illustration—and a second area 6b lying between pad row 2 and the arrays 3b, 3d—lying below in the illustration.

FIG. 3 shows a schematic representation of a semi-conductor component in terms of an embodiment example of the present invention, in particular the semi-conductor memory component 11.

The semi-conductor memory component 11 may for instance be a ROM or RAM component—e.g. one based on CMOS technology—e.g. a SRAM (SRAM=Static Random Access Memory) or DRAM (DRAM=Dynamic Random Access Memory), in particular e.g. a DDR-DRAM (DDR-DRAM=Double Data Rate DRAM and/or DRAM with double data rate).

The component 11 can be built into a housing provided with corresponding contact pins.

The housing-contact pins are connected—e.g. via bonding wires (not shown here)—to corresponding contact connections 12a, 12b, 12c (so-called “pads”) provided on the component 11.

In the semi-conductor memory component 11 data can be stored under an address—after this corresponding address has been applied to the housing address contact pins (not shown here), and thereby to the address input contact connections and/or pads of the memory component 11 connected to them—and later again read out under this address.

A number m of data contact connections and/or pads, e.g. m=16, 32, or 64 data connection pads—connected to corresponding housing data contact pins—are provided for inputting and outputting data.

By applying an appropriate signal (e.g. a read/write signal) to a corresponding read/write selection contact connection and/or pad—connected to a corresponding housing read/write contact pin—it can in each case be determined whether data is to be stored or read out.

The data input into the semi-conductor memory component 11 is stored there in corresponding memory cells and later read out again from the corresponding memory cell.

Each memory cell for instance consists of a few, in particular a single appropriately controlled transistor, with the capacitance of which one bit can in each case be stored as a charge.

A particular number of memory cells has in each case been arranged to lie in a rectangular and/or square matrix and/or array 13a, 13b, 13c, 13d, i.e. in a corresponding cell field, so that—according to the number of memory cells present—for instance 32 Mbit, 64 Mbit, 128 Mbit, 256 Mbit can be stored in a matrix and/or array 13a, 13b, 13c, 13d.

As is further shown in FIG. 3, the semi-conductor memory component 11 in each case contains a number k (here e.g. four, (alternatively e.g. two, eight, or sixteen, etc.)) essentially identically constructed memory cell arrays 13a, 13b, 13c, 13d, evenly distributed over the surface area of the components, so that a total memory capacity of e.g. 128 Mbit, 256 Mbit, 512 Mbit, and/or 1,024 Mbit (and/or 1 Gbit) is correspondingly created for the semi-conductor memory component 11.

The above address, applied to the address input contact connections and/or pads may contain a corresponding number (e.g. two) of bits, serving in each case to address the required memory cells array 13a, 13b, 13c, 13d during the storing or reading out data.

As is apparent from FIG. 3, the above contact connections and/or pads 12a, 12b, 12c (i.e. the data pads, the address pads, the read/write-selection pad, and further possible pads (not mentioned above), e.g. a chip select pad, and/or further control pads, etc., etc.)—are arranged to lie adjacent to each other, e.g. essentially equidistantly spaced from each other—in the form of a corresponding contact row 12 (pad row 12), which extends from the edge—lying on the left in the illustration—of the semi-conductor memory component 11 over the total width of the semi-conductor memory component 11 as far as an edge—lying on the right in the illustration—of the semi-conductor memory component.

The contact connections and/or pads 12a, 12b, 12c may have essentially identical dimensions, whereby their contact surfaces—lying at the top—may for instance have a rectangular, in particular a square (or e.g. an oval and/or round, etc.) cross-section when viewed from the top.

Instead of a single contact row 12, for instance two, three, or more further contact rows—lying essentially parallel next to each other—and otherwise arranged as illustrated above may also be provided.

As is apparent from FIG. 3, the contact row 12 (and/or—alternatively—the above, several contact rows (advantageously lying adjacent to each other)) is not arranged to lie exactly between the two arrays 3a, 3c (lying above in the illustration), and the arrays 3b, 3d (lying below in the illustration) of the central chip area (the so-called “spine”), but rather (as is more closely described below) relatively strongly displaced towards one of them—here: upwards in the direction of the arrays 13a, 13c (alternatively: downwards in the direction of the arrays 13b, 13d).

FIG. 4 shows a schematic detail representation of a section 14 of the semi-conductor memory component 11 shown in FIG. 3.

As is apparent from FIG. 4, a control logic 5, jointly allocated to all arrays 3a, 3b, 3c, 3d and/or jointly controlling them (as well as further elements, e.g. central data lines (central databus) jointly used by all the arrays 13a, 13b, 13c, 13d—and/or further—central or decentralized—logic elements and/or—circuits, lines etc.) containing corresponding elements 15a, 15b, 15c, 15d, etc. securing the functionality of the semi-conductor memory component 11 (e.g. appropriate multiplexers and/or de-multiplexers, timers, registers, lines, etc.), has been provided in a central chip area (the so-called “spine”)—lying exactly between the two arrays 13a, 13c (lying above in the illustration), and the arrays 13b, 13d (lying below in the illustration)—, as well as in an area bordering on it, here: lying below it, between the spine area and the (here: bottom) arrays 13b, 13d, extending to the edge of the (here: bottom) arrays 13a, 13d, i.e. completely in an area—identified in FIG. 4 with the reference number “16”—which contains these two areas.

As is apparent from FIG. 4, all the above elements 15a, 15b, 15c, 15d (i.e. the elements allocated to the central control logic 15), as well as—additionally—all or the majority of the above—further—elements (e.g. the above central data bus, logic circuits, etc.) are always simply arranged on the area 16 (here shown lying below) the contact row 12—and not for instance (additionally) on an area lying between contact row 12 and the arrays 13a, 13c (here shown lying above).

In contrast to this—as is apparent from FIG. 4—the memory component area 17, in which the above contacts and/or pads 12a, 12b, 12c (i.e. the above—one or more—contact row(s) 12)) have been arranged extends directly to or bordering onto the (here: top) arrays 13a, 13d (and/or the respective cells or (here: top) cell fields).

Advantageously the area 17, to which the above contact row(s) 12 have been allocated, e.g. lies above the central axis a shown in FIG. 4, running exactly midway between the—upper—arrays 13a, 13c, and the—lower—arrays 13b, 13d (whereby—according to FIG. 4—the distance b between the central axis a, and the (here: lower) edge of the areas 17, and the distance c between the central axis a, and the (here: lower) edge of the (here: top) arrays 13a, 13d e.g. may be in the following ratio: b/c>0.2, in particular e.g. b/c>0.4, or e.g. b/c>0.6 and/or b/c>0.7, etc.).

As is apparent from FIG. 4—in particular in comparison to FIG. 2—relatively large elements, in particular elements pre-designed for numerous different memory component designs (pre-synthetised, “modular” elements, which are or could be similarly used for numerous further semi-conductor memory components 11′, 11″, 11′″ that are different to the semi-conductor memory component 11) can be used in the semi-conductor memory component 11 in particularly advantageous fashion, in particular for the above elements 15a, 15b, 15c, 15d of the central control logic 15, and/or for the above—further—elements (e.g. the above central data bus, etc.), which is particularly facilitated by the relatively large width d of the above component area 16 as illustrated in FIG. 4.

This leads to shorter development times than for conventional semi-conductor memory components 1 corresponding to those constructed as shown in FIGS. 1 and 2.

### REFERENCE NUMBERS

1 Semi-conductor memory component
2 Pad row
2a Pad
2b Pad
2c Pad
3a Matrix
3b Matrix
3c Matrix
3d Matrix
4 Semi-conductor memory element section
5 Central control logic
5a Control logic element
5b Control logic element
5c Control logic element
5d Control logic element
6a Component area
6b Component area
11 Semi-conductor
12 Pad row
12a Pad
12b Pad
12c Pad
13a Matrix
13b Matrix
13c Matrix
13d Matrix
14 Semi-conductor memory component section
15 Central control logic
15a Control logic element
15b Control logic element
15c Control logic element
15d Control logic element
16 Component area
17 Component area

1. A memory component (11), with numerous contact connections (12a, 12b, 12c) and with at least two memory cell arrays (13a, 13b), each comprising numerous memory cells
characterized in that
the contact connections (12a, 12b, 12c) are arranged in an area (17) between a central axis (a) which runs between the arrays (13a, 13b), in particular the spine of the memory component (11), and one of the arrays (13a).

2. A memory component (11) according to claim 1, in which the contact connections (12a, 12b, 12c) are arranged to lie adjacent to each other in a row (2).

3. A memory component (11) according to claim 1, in which the contact connections (12a, 12b, 12c) are arranged to lie adjacent to each other in several rows, in particular in parallel rows.

4. A memory component (11) according to claim 1, in which the area (17), in which the contact connections (12a, 12b, 12c) are arranged, is directly adjacent to the one of the arrays (13a).

5. A memory component (11) according to claim 1, in which elements (15a, 15b, 15c, 15d) of a central control logic (15), which jointly controls at least two arrays (13a, 13b), are arranged in an additional area (16) lying between the area (17) in which the contact connections (12a, 12b, 12c) are arranged, and another one of the arrays (13b).

6. A memory component (11) according to claim 5, in which all the elements (15a, 15b, 15c, 15d) of the central control logic (15) lie in the additional area (16).

7. A memory component (11) according to claim 5, in which the additional area (16) is directly adjacent to the other one of the arrays (13b).

8. A memory component (11) according to claim 5, in which the area (17) is directly adjacent to the additional area (16).

9. A memory component (11) according to claim 5, in which the distance b between the central axis (a), and the immediately adjacent edge of the area (17), and the distance c between the central axis (a), and the immediately adjacent edge of the one of the arrays (13a) is in the following ratio: b/c>0.2, in particular b/c>0.4.

10. A memory component (11) according to claim 5, which has more than ten, in particular more than 20 contact connections (12a, 12b, 12c).

11. A memory component (11) according to claim 5, which has more than three, in particular four, or more than six, in particular nine or sixteen memory cell arrays.

12. A memory component (11) according to claim 5, in which more than 30 Mbit, in particular more than 60 Mbit, more than 120 Mbit, or more than 250 Mbit can be stored in a memory cell array (13a, 13b, 13c, 13d).

13. A memory component (11) according to claim 5, which is a DRAM (Dynamic Random Access Memory).

14. A memory component (11) according to claim 5, which is a DDR (Double Data Rate) semi-conductor memory component.

15. A memory component (11) according to claims 5, in which for the elements (15a, 15b, 15c, 15d) of the central control logic (15) pre-synthesized elements are used which were jointly designed for several different memory components (11, 11′, 11″, 11′″).
